(19) United States
(12) Patent Application Publication
(10) Pub. No.: US 2012/0146067 A1
(43) Pub. Date: Jun. 14, 2012

(54) LIGHT EMITTING DEVICE

(75) Inventor: Tsunehiro UNNO, Hitachi (JP)

(73) Assignee: Hitachi Cable, Ltd., Tokyo (JP)

(21) Appl. No.: 13/309,467

(22) Filed: Dec. 1, 2011

(30) Foreign Application Priority Data
Dec. 14, 2010 (JP) 2010-277879

(51) Int. Cl. H01L 33/60; H01L 33/62

(52) U.S. Cl. 257/91; 257/99; 257/E33.06; 257/E33.062

(57) ABSTRACT

A light emitting device includes a supporting substrate, a first conductivity type layer of a first conductivity type provided on the supporting substrate, an active layer provided on the first conductivity type layer, a second conductivity type layer of a second conductivity type provided on the active layer, a first electrode being in contact with a part of the surface of the first conductivity type layer, and a second electrode being in contact with a part of the surface of the second conductivity type layer. The first electrode is in contact with a surface of the first conductivity type layer, and the surface is different from a surface of the first conductivity type layer corresponding to a region located directly above or below the active layer.

The present application is based on Japanese Patent Application No. 2010-277879 filed on Dec. 14, 2010, the entire contents of which are incorporated herein by reference.

### BACKGROUND OF THE INVENTION

1. Field of the Invention

The present invention relates to a light emitting device.

2. Related Art

In accordance with a trend of production discontinuance of incandescent light bulbs, light emission efficiency of a light-emitting diode has been improved. Therefore, the use of light-emitting diode for lighting instead of the incandescent light bulb is increased. Also, it is supposed that if the light emission efficiency of the light-emitting diode is further enhanced, the use of the light-emitting diode for lighting purpose instead of a fluorescent light tube will be further increased. Consequently, the enhancement of the light emission efficiency of the light-emitting diode is important in terms of not only mere energy saving but also production cost reduction and reliability improvement of the light-emitting diode for realizing brightness equal or superior to the fluorescent light tube or the like.

As a conventional light emitting device, a light-emitting diode having a flip-chip structure in which no electrode is formed on a front surface side of the light-emitting diode chip has been known (e.g. Japanese Translation of PCT International Application Publication No. JP-T-2008-523637). The light emitting device described in JP-T-2008-523637 has a structure in which both of positive and negative electrodes are formed on a back surface side of an epitaxial layer, so that when the light is emitted from the front surface of the chip, the light is not blocked. Therefore, in the light emitting device described in JP-T-2008-523637, the light extraction efficiency can be enhanced up to approximately 70%.

### SUMMARY OF THE INVENTION

However, in the light emitting device described in JP-T-2008-523637, although a photoelectric conversion efficiency has been improved up to around 55%, approximately half energy supplied to the light emitting device cannot be extracted as a light to the outside of the light emitting device The energy that cannot be extracted to the outside of the light emitting device is converted to heat, and the heat is emitted from the light emitting device. Here, the energy emitted from the light emitting device as heat causes not only mere decrease in the photoelectric conversion efficiency but also increase in temperature of the light emitting device. In the case that the temperature of the light emitting device is increased, the decrease in the photoelectric conversion efficiency and lifetime of the light emitting device may be caused.

Accordingly, an object of the present invention is to provide a light emitting device with a high light emitting efficiency.

In order to solve the above-mentioned problem, the present invention provides the light emitting device described below.

According to a feature of the invention, a light emitting device comprises:

a supporting substrate;

a first conductivity type layer of a first conductivity type provided on the supporting substrate;

an active layer provided on the first conductivity type layer, which emits a light;

a second conductivity type layer of a second conductivity type provided on the active layer, the second conductivity type being different from the first conductivity type;

a first electrode being in contact with a part of a surface of the first conductivity type layer; and

a second electrode being in contact with a part of a surface of the second conductivity type layer,

in which the first electrode is in contact with a surface of the first conductivity type layer, the surface being different from a surface of the first conductivity type layer corresponding to a region located directly above or below the active layer,

in which the second electrode is in contact with a surface of the second conductivity type layer, the surface being different from a surface of the second conductivity type layer corresponding to a region located directly above or below the active layer.

In the light emitting device, the first electrode may comprise a plurality of electrodes and the second electrode may comprise a plurality of electrodes, the first electrode and the second electrode may be formed in a linear shape respectively in a plan view, and the first electrode and the second electrode may be arranged parallel to each other in a plan view.

The light emitting device may further comprise:

a plurality of light emitting portions provided on the supporting substrate, each of the light emitting portions comprising the first conductivity type layer and the active layer and being separated from each other by a plurality of grooves,

in which the second electrode is provided on a surface of the second conductivity type layer located below each of the plurality of grooves and the surface is located on an opposite side of the active layer,

in which the first electrode is provided on a surface of the first conductivity type layer in each of the plurality of light emitting portions, and the surface is located on a side of the second conductivity type layer and on which the active layer is not provided.

The light emitting device may further comprise:

a reflecting portion provided between the supporting substrate and the second conductivity type layer, which reflects the light toward the first conductivity type layer, and

a transparent insulation layer provided on a region between the reflecting portion and the second conductivity type layer, the region being different from a region on which the second electrode is provided, which transmits the light and has an electrical insulating property.

In the light emitting device, the first electrode in one light emitting portion and the second electrode in an other light emitting portion adjacent to the one light emitting portion may be electrically connected to each other, thereby the one light emitting portion and the other light emitting portion are electrically connected in series.

In the light emitting device, the first electrode in one light emitting portion and the first electrode in an other light emitting portion adjacent to the one light emitting portion may be electrically connected to each other, and the second electrode in the one light emitting portion and the second electrode in the other light emitting portion adjacent to the one light emitting portion may be electrically connected to each other, thereby the one light emitting portion and the other light emitting portion are electrically connected in parallel.

According to another feature of the invention, a light emitting device comprises:

a supporting substrate;

a first conductivity type layer of a first conductivity type provided on the supporting substrate;

an active layer provided on the first conductivity type layer, which emits a light;

a second conductivity type layer of a second conductivity type provided on the active layer; the second conductivity type being different from the first conductivity type;

a first electrode being in contact with a surface of the first conductivity type layer, the surface being located on an opposite side of the active layer and located distant from a region located directly below the active layer;

a second electrode being in contact with a part of a surface of the second conductivity type layer, the surface being located on an opposite side of the active layer; and an insulation portion provided on a region corresponding to a region located directly below the second electrode instead of the active layer.

According to a still another feature of the invention, a light emitting device comprises:

a supporting substrate;

a first conductivity type layer of a first conductivity type provided on the supporting substrate;

an active layer provided on the first conductivity type layer, which emits a light;

a second conductivity type layer of a second conductivity type provided on the active layer, the second conductivity type being different from the first conductivity type;

a first electrode being in contact with a surface of the first conductivity type layer, the surface being located on a side of the active layer and exposed from a region in which the active layer is removed;

a second electrode being in contact with a part of a surface of the second conductivity type layer, the surface being located on an opposite side of the active layer; and

an insulation portion provided on a region corresponding to a region located directly below the second electrode instead of the active layer.

### (Points of the Invention)

According to the light emitting device of the present invention, a first electrode is in contact with one part of a surface of the first conductivity type layer, and a second electrode is in contact with one part of a surface of the second conductivity type layer. The one part of the surface of the first conductivity type layer is different from another part of the surface of the first conductivity type layer corresponding to a region located directly above or below an active layer, and the one part of the surface of the second conductivity type layer is different from another part of the surface of the second conductivity type layer corresponding to a region located directly above or below the active layer. Therefore, it is possible to provide a light emitting device with high light emitting efficiency.

### BRIEF DESCRIPTION OF THE DRAWINGS

The preferred embodiments according to the invention will be explained below referring to the drawings:

FIG. 1A is a perspective view schematically showing a light emitting device according to one embodiment of the present invention;

FIG. 1B is a cross-sectional view taken along the line A-A in FIG. 1A;

FIG. 1C is a plan view schematically showing an arrangement of a reflecting portion, a pad electrode for n-type and a pad electrode for p-type used in the light emitting device according to the embodiment of the present invention;

FIGS. 2A to 2M are cross-sectional views schematically showing a flow of a manufacturing process of the light emitting device according to the embodiment of the present invention;

FIG. 3 is a cross-sectional view schematically showing a light emitting device according to a first modification of the embodiment of the present invention;

FIG. 4 is a cross-sectional view schematically showing a light emitting device according to a second modification of the embodiment of the present invention;

FIG. 5 is a cross-sectional view schematically showing a light emitting device according to a third modification of the embodiment of the present invention; and

FIG. 6 is a cross-sectional view schematically showing a light emitting device according to a fourth modification of the embodiment of the present invention.

### DETAILED DESCRIPTION OF THE EMBODIMENT

### Summary of the Embodiment

A light emitting device according to the present invention includes a supporting substrate, a first conductivity type layer of a first conductivity type provided on the supporting substrate, an active layer provided on the first conductivity type layer, which emits a light,a second conductivity type layer of a second conductivity type provided on the active layer, the second conductivity type being different from the first conductivity type, a first electrode being in contact with a part of a surface of the first conductivity type layer, and a second electrode being in contact with a part of a surface of the second conductivity type layer in which the first electrode is in contact with a surface of the first conductivity type layer, the surface being different from a surface of the first conductivity type layer corresponding to a region located directly above or below the active layer, in which the second electrode is in contact with a surface of the second conductivity type layer, the surface being different from a surface of the second conductivity type layer corresponding to a region located directly above or below the active layer.

In other words, a light emitting device according to the present invention includes a supporting substrate, a first conductivity type layer of a first conductivity type provided on the supporting substrate, an active layer provided on the first conductivity type layer, which emits a light, a second conductivity type layer of a second conductivity type provided on the active layer, the second conductivity type being different from the first conductivity type, a first electrode being in contact with one part of a surface of the first conductivity type layer, and a second electrode being in contact with one part of a surface of the second conductivity type layer, in which the one part of the surface of the first conductivity type layer is different from another part of the surface of the first conductivity type layer corresponding to a region located directly above or below the active layer, in which the one part of the surface of the second conductivity type layer is different from another part of the surface of the second conductivity type layer corresponding to a region located directly above or below the active layer.

In the light emitting device 1 according to the embodiment, a region on which an active layer 16 is provided is definitely separated from regions on which an n-side contact electrode 60 and a p-side contact electrode 65 are provided, in order to reduce a light absorbed by the n-side contact electrode 60 and p-side contact electrode 65 in the case that a light emitted in the active layer 16 is extracted to the outside of the light emitting device 1 while the light is multiply-reflected in the light emitting device 1. Also, in the light emitting device 1, intervals are arranged between the n-side contact electrode 60 and p-side contact electrode 65 to be approximately constant in a plan view so that it is possible to prevent electric current from being locally concentrated to the active layer 16.

### The Embodiment

Next, the embodiment according to the present invention will be explained in more detail in conjunction with the appended drawings.

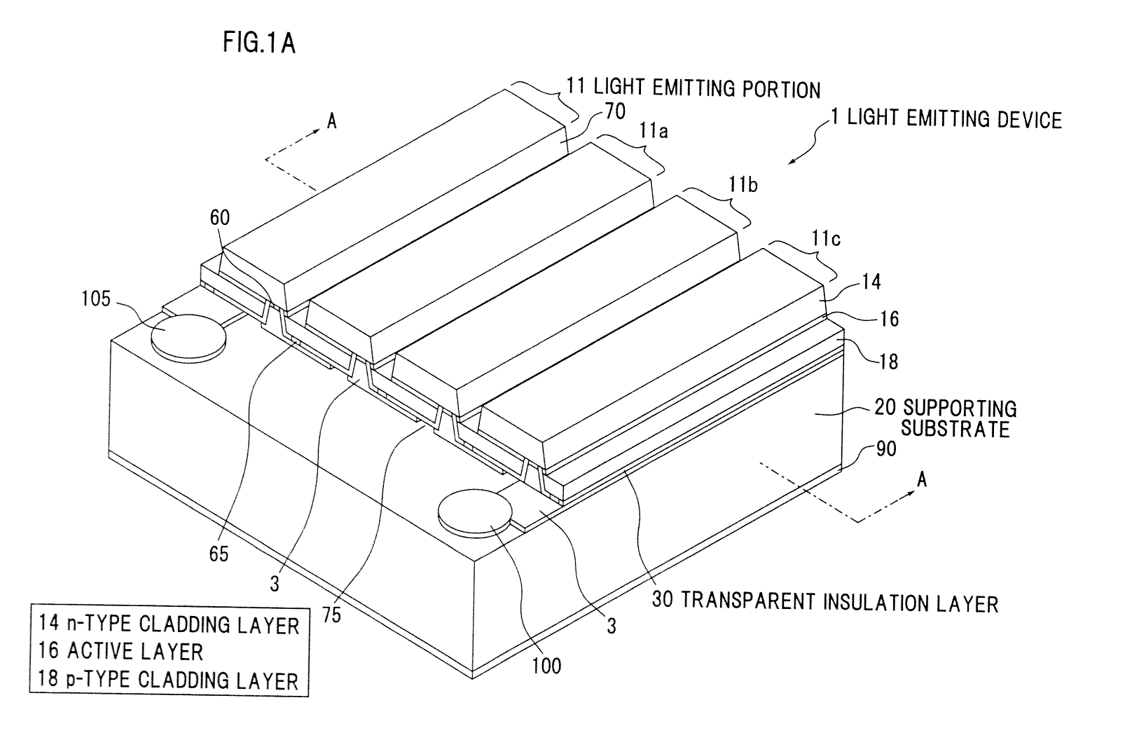

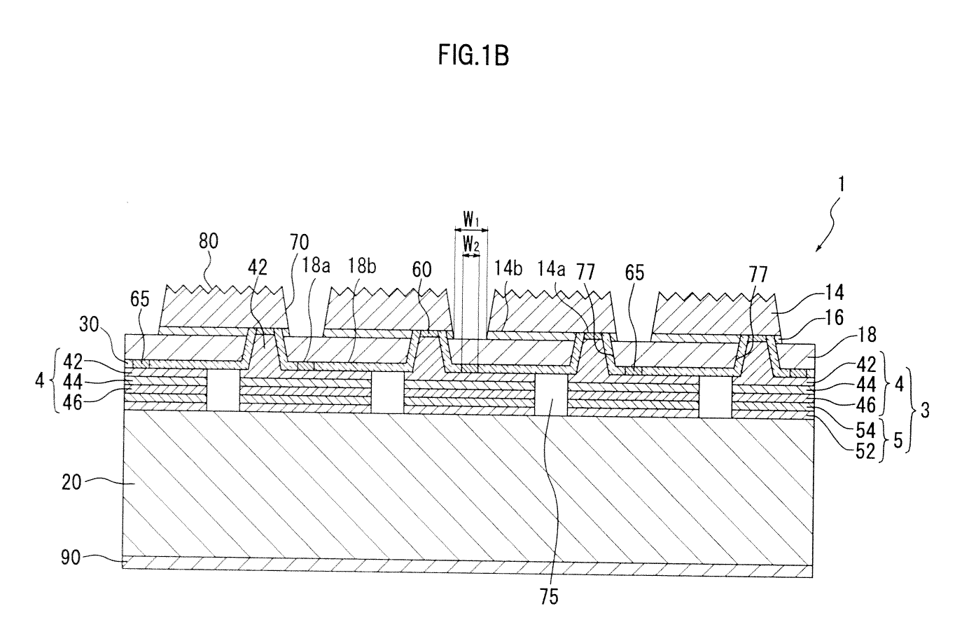

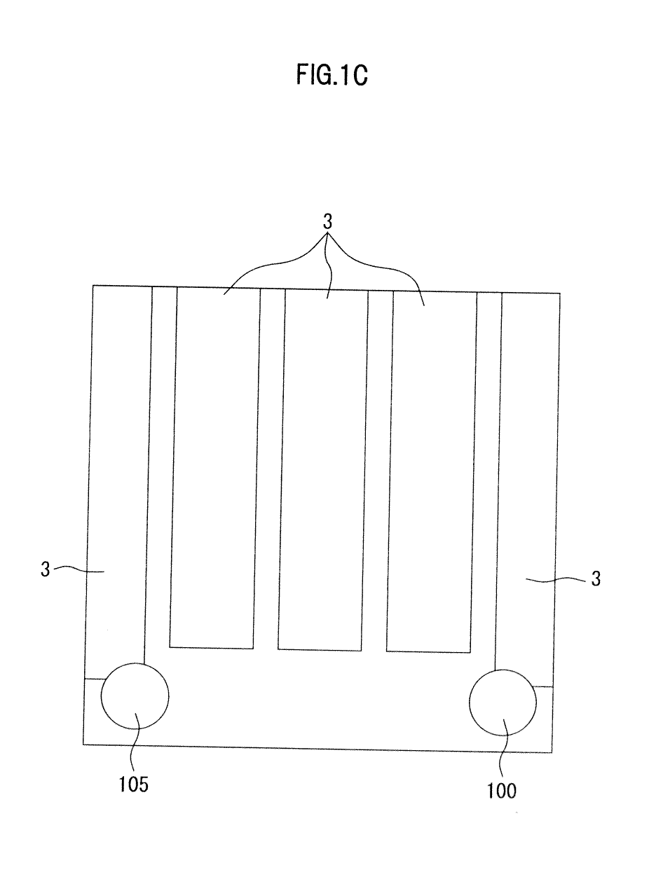

FIG. 1A is a perspective view schematically showing a light emitting device according to one embodiment of the present invention, and FIG. 1B is a cross-sectional view taken along the line A-A in FIG. 1A. In addition, FIG. 1C is a plan view schematically showing an arrangement of a reflecting portion, a pad electrode for n-type and a pad electrode for p-type used in the light emitting device according to the embodiment of the present invention. Further, in FIG. 1A, for convenience of explanation, convexo-concave portions are omitted.

### (Outline of Structure of Light Emitting Device 1)

The light emitting device 1 according to the embodiment is a light emitting diode (LED), as an example, a flip-chip type light emitting device for emitting a red light, which mainly includes an AlGaInP based group III-V compound semiconductor. The light emitting device 1 is configured to have, as an example, a rectangular shape. In particular, the light emitting device 1 includes a supporting substrate 20, a supporting substrate-side bonding layer 5 provided on the supporting substrate 20, a semiconductor-side bonding layer 4 provided on the supporting substrate-side bonding layer 5 and forming a metal bonding together with the supporting substrate-side bonding layer 5, a transparent insulation layer 30 provided on the semiconductor-side bonding layer 4 and having an electrical insulating property, and a compound semiconductor layer provided on the transparent insulation layer 30. On a back surface of the supporting substrate 20 (i.e. a surface of the supporting substrate opposite to a front surface on which the supporting substrate-side bonding layer 5 is provided), a metal layer 90 is provided as a metal layer for a die-bonding including a metallic material for the purpose of facilitating the die-bonding in the case of mounting the light emitting device 1 on a member such as stem.

The supporting substrate-side bonding layer 5 includes a cohesion layer 52 and a supporting substrate-side bonding metal layer 54 sequentially from a side of the supporting substrate 20. In addition, the semiconductor-side bonding layer 4 includes a reflecting layer 42, a diffusion suppressing layer 44 and a semiconductor-side bonding metal layer 46 sequentially from a side of the transparent insulation layer 30. The supporting substrate-side bonding metal layer 54 and the semiconductor-side bonding metal layer 46 form a metal-bonding, thereby the supporting substrate-side bonding layer 5 and the semiconductor-side bonding layer 4 are integrated. The supporting substrate-side bonding layer 5 and the semiconductor-side bonding layer 4 are integrated to provide the reflecting portion 3. The reflecting portion 3 includes a plurality of grooves 75 for dividing the reelecting portion 3 at a predetermined interval in a thickness direction of the light emitting device 1. The reflecting portion 3 is divided into a plurality of regions by the plurality of grooves 75. For example, as shown in FIG. 1C, the reflecting portion 3 is configured to have a plurality of linear patterns in a plan view.

Here, as to the plurality of reflecting portions 3, one reflecting portion 3 is provided adjacent to one side in a plan view of the light emitting device 1 and another reflecting portion 3 is provided adjacent to the opposite side of the one side of the light emitting device 1. Each of the one reflection portion 3 and another reflection portion 3 is formed to have a long side longer than a long side of each of the plurality of reflecting portions 3 located between the one reflecting portion 3 and another reflecting portion 3. Also, as shown in FIGS. 1A and 1C as an example, end portions of the one reflecting portion 3 and the another reflecting portion 3 are exposed in regions where all or a part of the compound semiconductor layer and the transparent insulation layer 30 adjacent to a side perpendicular to the one side and the opposite side are removed. In addition, a pad electrode for p-type 105 is electrically connected to the end portion of the one reflecting portion 3. On the other hand, a pad electrode for n-type 100 is electrically connected to the end portion of another reflecting portion 3. Further, the reflecting portion 3 may be provided directly below the pad electrode for p-type 105 and the pad electrode for n-type 100.

The compound semiconductor layer includes a p-type cladding layer 18 as a first conductivity type layer of a first conductivity type provided above the supporting substrate 20 via the reflecting portion 3 and the transparent insulation layer 30, an active layer 16 provided on the p-type cladding layer 18, which emits a light, and an n-type cladding layer 14 as a second conductivity type layer of a second conductivity type provided on the active layer 16. In addition, convexo-concave portions 80 are provided on a surface of the n-type cladding layer 14.

Here, the light emitting device 1 includes a plurality of grooves 77 formed by removing a part of the p-type cladding layer 18 and a part of the active layer 16 at a plurality of sites along the thickness direction of the light emitting device 1 from the p-type cladding layer 18 toward the active layer 16. The transparent insulation layer 30 is in contact with side surfaces of the plurality of grooves 77. Namely, the transparent insulation layer 30 is in contact with side surfaces of the p-type cladding layer 18 and side surfaces of the active layer 16 that are exposed by forming the grooves 77. Further, each of the grooves 77 has, as an example, a linear shape in a plan view.

In addition, a part of the reelecting layer 42 is filled in each of the grooves 77 that are insulated by the transparent insulation layer 30. Further, the n-side contact electrode 60 as the second electrode is provided on a surface 14a of the n-type cladding layer 14 that is located within the groove 77 and is exposed by removing a part of the p-type cladding layer 18 and a part of the active layer 16. Consequently, the reflecting layer 42 and the n-type cladding layer 14 are electrically connected to each other via the n-side contact electrode 60 that is in contact with a part (i.e. the surface 14a) of a surface of the n-type cladding layer 14. In addition, a through hole 30a formed in a part of the transparent insulation layer 30 is filled to provide the p-side contact electrode 65, so that the p-type cladding layer 18 and the reflecting layer 42 are electrically connected to each other via the p-side contact electrode 65 as the first electrode that is in contact with a part of a surface 18a of the p-type cladding layer 18.

Consequently, the n-side contact electrode 60 is in contact with the surface 14a of the n-type cladding layer 14. The surface 14a is different from a surface 14b of the n-type cladding layer 14 corresponding to a region located directly above or below the active layer 16. Similarly, the p-side contact electrode 65 is in contact with the surface 18a of the p-type cladding layer 18. The surface 18a is different from a surface 18b of the p-type cladding layer 18 corresponding to a region located directly above or below the active layer 16.

Here, since the light emitting device 1 includes the plurality of grooves 77, the n-side contact electrode 60 is provided in each of the grooves 77. In addition, the transparent 10 insulation layer 30 has a plurality of through holes 30a at a predetermined interval. Further, since the p-side contact electrode 65 is provided in each of the through holes 30a, the light emitting device 1 includes a plurality of p-side contact electrodes 65. In addition, each of the n-side contact electrode 60 and the p-side contact electrode 65 is formed to have a linear shape in a plan view. Furthermore, the n-side contact electrode 60 and the p-side contact electrode 65 are arranged in parallel in a plan view.

The light emitting device 1 includes the n-type cladding layer 14 and the active layer 16 on the supporting substrate 20, and includes a plurality of light emitting portions 11, 11a, 11b and 11c that are divided from each other by the plurality of grooves 77. Each of the light emitting portions 11 to 11c has a linear shape in a plan view. Further, the number of the light emitting portions is not limited to four, but the number may be “n” (“n” is an integer not less than 2). In addition, the p-side contact electrode 65 is provided on the surface 18a of the p-type cladding layer 18 located below each of the grooves 70, and the surface 18a is located on an opposite side of the active layer 16. Further, the n-side contact electrode 60 is provided on the surface 14a of the n-type cladding layer 14 of each of plural light emitting portions 11 to 11c, The surface 14a is located on a side of the p-type cladding layer 18 in which the active layer 16 is not provided.

Here, the one light emitting portion 11a is sandwiched between the first groove 70 and the second groove 70. In addition, the p-side contact electrode 65 located below the first groove 70 and the p-side contact electrode 65 located below the second groove 70 are electrically insulated from each other by a plurality of grooves 75. Namely each of the p-side contact electrodes 65 is electrically insulated from each other by the plurality of grooves 75. On the other hand, the n-side contact electrode 60 of the one light emitting portion and the p-side contact electrode 65 located below the second groove 70 are electrically connected to each other via the reflecting portion 3 (more particularly, the reflecting layer 42). In addition, the p-side contact electrode 65 located below the first groove 70 and the n-side contact electrode 60 of the one light emitting portion 11a are electrically connected to each other via the n-type cladding layer 14, the active layer 16 and the p-type cladding layer 18. The other light emitting portions 11, 11b, and 11c have the same structure as the one light emitting portion 11a respectively.

Accordingly, the one light emitting portion (e.g. 11a) and the other light emitting portion (e.g. 11) adjacent to the one light emitting portion (e.g. 11a) are electrically connected to each other in series. Namely, the n-side contact electrode 60 of the one light emitting portion 11a and the p-side contact electrode 65 of the other light emitting portion 11 adjacent to the one light emitting portion 11a are electrically connected to each other, so that the one light emitting portion 11a and the other light emitting portion 11 are electrically connected to each other in series. Further, a width W₁ of the groove 70 (namely a distance between the one light emitting portion 11a and the other light emitting portion 11) is formed wider than a width W₂ of the p-side contact electrode 65.

Further, for the purpose of reducing contact resistance of the contact electrode, a p-type contact layer that has carrier concentration higher than the p-type cladding layer 18 may be also formed on the p-type cladding layer 18 located on an opposite side of the active layer 16. Similarly, an n-type contact layer that has a carrier concentration higher than the n-type cladding layer 14 may be formed on the n-type cladding layer 14 located on an opposite side of the active layer 16. Further, for the purpose of enhancing dispersion of electrical current supplied to the light emitting device 1, improving light emission efficiency of the light emitting device 1 and reducing forward voltage, a current dispersion layer that has resistance lower than those of the p-type contact layer and the n-type contact layer may be provided between the p-type cladding layer 18 and the p-type contact layer and/or between the n-type cladding layer 14 and the n-type contact layer.

In addition, in FIG. 1A, a surface of the supporting substrate 20 is partially exposed, except for a region on which the reflecting portion 3, the pad electrode for n-type 100 and the pad electrode for p-type 105 are provided and a region on which the light emitting portions 11 to 11c are provided. For example, the transparent insulation layer 30 may be provided on the exposed surface.

### (Supporting Substrate 20)

The supporting substrate 20 may comprise a substrate having high electrical resistance for the purpose of electrically separating the light emitting portions 11 to 11c from each other. In addition, the supporting substrate 20 may comprise a material having a mechanical strength and a thickness capable of resisting a force applied to the light emitting device 1 during the manufacturing process and the use of the light emitting device 1. For example, the supporting substrate 20 may comprise a Si substrate. The Si substrate may comprise e.g. a high resistance Si substrate having resistivity of not less than 3×10⁴ Ωcm. Also, the metal layer 90 provided on the back surface of the supporting substrate 20 (i.e. the opposite surface of the surface on which the reflecting portion 3 is provided) may comprise e.g. an AuSn layer which is an alloy material for eutectic bonding may be used for the purpose of enhancing heat dissipation from the light emitting device 1. Further, the supporting substrate 20 may comprise a Si substrate having low heat resistance and high carrier concentration on a surface of which a SiO₂ film is formed as an insulating film to exhibit insulation property.

### (Supporting Substrate-Side Bonding Layer 5)

The supporting substrate-side bonding layer 5 is provided on the front surface of the supporting substrate 20 (i.e. the opposite surface of the back surface) so as to have a predetermined pattern. More concretely, the supporting substrate-side bonding layer 5 includes the cohesion layer 52 formed of a metal such as Ti for making the supporting substrate 20 cohere with the supporting substrate-side bonding metal layer 54, and the supporting substrate-side bonding metal layer 54 formed of a metal such as Au, sequentially from a side of the front surface of the supporting substrate 20. The supporting substrate-side bonding metal layer 54 has a function of bonding to the semiconductor-side bonding metal layer 46.

### (Semiconductor-Side Bonding Layer 4)

The semiconductor-side bonding layer 4 includes a single layer of metal or a plurality of metal layers. For example, the semiconductor-side bonding layer 4 may comprise a semiconductor-side bonding metal layer 46, a diffusion suppressing layer 44 and a reflecting layer 42 for reflecting a light emitted from the active layer 16 sequentially from a side of the supporting substrate 20. The semiconductor-side bonding metal layer 46 may comprise a metal such as Au, and the diffusion suppressing layer 44 may comprise a metal such as Ti, Pt. In addition, the reflecting layer 42 comprises a metal such as Au. In this case, the semiconductor-side bonding metal layer 46 fulfills a function of bonding to the supporting substrate-side bonding metal layer 54. Further, the diffusion suppressing layer 44 fulfills a function as a diffusion-preventing barrier layer for suppressing the change of the reflecting layer 42 in reflection characteristics caused by diffusion of materials constituting the supporting substrate 20 and the like into the reflecting layer 42.

Further, the reflecting layer 42 may comprise a metal having a high reflectance with respect to a wavelength of a light emitted from the active layer 16 (e.g. a metal having a reflectance of not less than 80%). In addition, the reflecting portion 3 configured to have the semiconductor-side bonding layer 4 and the supporting substrate-side bonding layer 5 has a function of connecting the compound semiconductor layer and the supporting substrate 20, and simultaneously has a function of reflecting the light emitted from the active layer 16, since the reflecting portion 3 is in contact with the transparent insulation layer 30.

### (Transparent Insulation Layer 30)

The transparent insulation layer 30 transmits the light emitted from the active layer 16. In addition, the transparent insulation layer 30 comprises a material having an electrical insulating property. For example, the transparent insulation layer 30 may comprise SiO₂ or SiN. As an example, the transparent insulation layer 30 is formed of SiO₂.

### (Compound Semiconductor Layer)

The compound semiconductor layer includes the p-type cladding layer 18, the active layer 16 and the n-type cladding layer 14 sequentially from a side of the supporting substrate 20. Each layer of the compound semiconductor layer comprises a compound semiconductor layer represented by (AlₓGa₁₋ₓ)_{y}In_{1-y}P (here, satisfying 0<x<1, and 0<y<1), GaP or GaAs. For example, the cladding layer 18 comprises a p-type (AlₓGa₁₋ₓ)_{y}In_{1-y}P. The active layer 16 comprises a quantum well structure including a plurality of pairs of a barrier layer and a well layer including an undoped (AlₓGa₁₋ₓ)_{y}In_{1-y}P. In addition, the n-type cladding layer 14 comprises an n-type (AlₓGa₁₋ₓ)_{y}In_{1-y}P.

Further, a p-type contact layer may be provided on the p-type cladding layer 18 on the opposite side of the active layer 16. In this case, the p-type contact layer may comprise a p-type GaP. In addition, an n-type contact layer may be provided on the n-type cladding layer 14 on the opposite side of the active layer 16. In this case, the n-type contact layer may comprise an n-type GaAs.

The p-side contact electrode 65 that electrically connects the p-type cladding layer 18 and the reflecting layer 42 to each other via an opening provided in the transparent insulation layer 30 is provided on a part of the surface of the p-type cladding layer 18 located on the opposite side of the active layer 16. The p-side contact electrode 65 has e.g. a linear shape in a plan view. In addition, the p-side contact electrode 65 is located below the groove 70. Further, the p-side contact electrode 65 comprises a material that is brought into ohmic-contact with the p-type cladding layer 18.

The n-side contact electrode 60 is provided on a part (i.e. the surface 14a) of the surface of the n-type cladding layer 14. The surface 14a is located on a side of the supporting substrate 20 and from which parts of the p-type cladding layer 18 and the active layer 16 are removed. In particular, the grooves 77 are formed on the n-type cladding layer 14 located on the side of the supporting substrate 20 by partially removing the p-type cladding layer 18 and the active layer 16, and the transparent insulation layer 30 is formed on the surfaces of the grooves 77 In addition, the n-side contact electrode 60 is formed on the surface 14a of the n-type cladding layer 14, and the surface 14a is exposed from the grooves 77 at a region where the transparent insulation layer 30 is not formed. The n-side contact electrode 60 has e.g. a linear shape in a plan view. Further, the n-side contact electrode 60 comprises a material that is brought into ohmic-contact with the n-type cladding layer 14.

### (Convexo-Concave Portions 80)

The convexo-concave portions 80 are formed by roughening a surface (i.e. a light extraction surface) of the n-type cladding layer 14 located on the opposite side of the active layer 16. The convexo-concave portions 80 are formed on the surface to have a predetermined pattern. In addition, the convexo-concave portions 80 may be formed to have a random shape by etching the surface with the use of a predetermined etchant. Furthermore, the convexo-concave portions 80 are formed to have a height within a range of a maximum height Ry that is determined in accordance with the wavelength of the light emitted from the active layer 16 for the purpose of enhancing the light extraction efficiency of the light emitting device 1. For example, in the case that the emission wavelength is 460 nm, the convexo-concave portions 80 are formed to have the maximum height Ry of not less than 230 nm which is a half of the emission wavelength of 460 nm e.g. not less than 0.2 μm. In addition, the convexo-concave portions 80 may be formed by using an optical photolithography technology, an electron beam printing technology or a nanoimprint technology. In the case that the optical photolithography technology is used in order to reduce the manufacturing cost of the light emitting device 1, the maximum height Ry of the convexo-concave portions 80 may be set within a range of approximately not less than 0.5 μm and not more than 3.0 μm.

### (Manufacturing Method of Light Emitting Device 1)

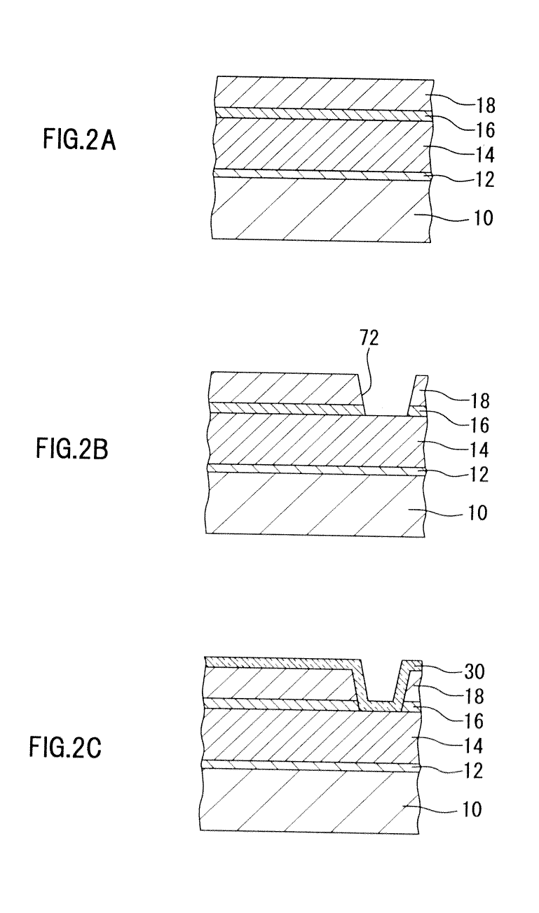

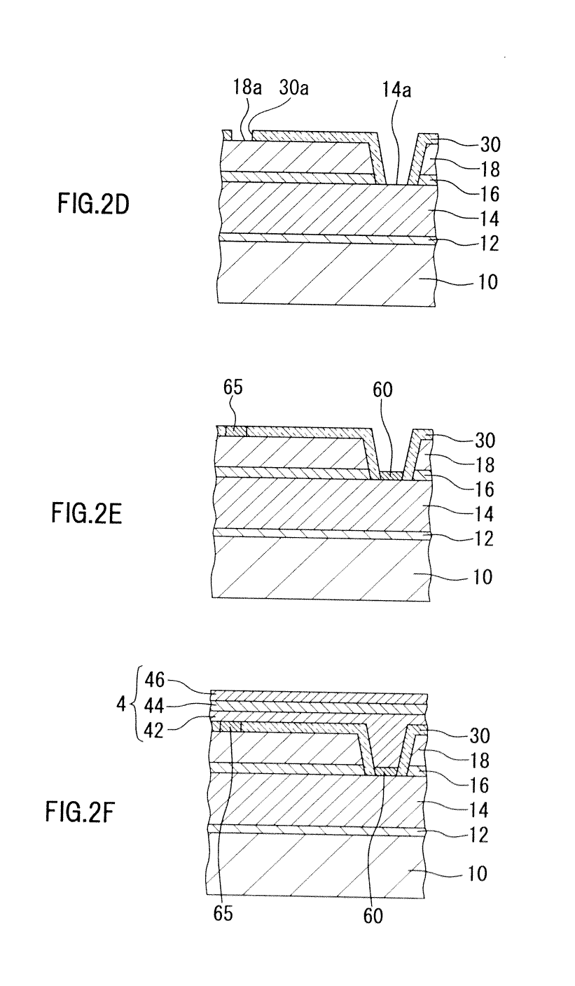

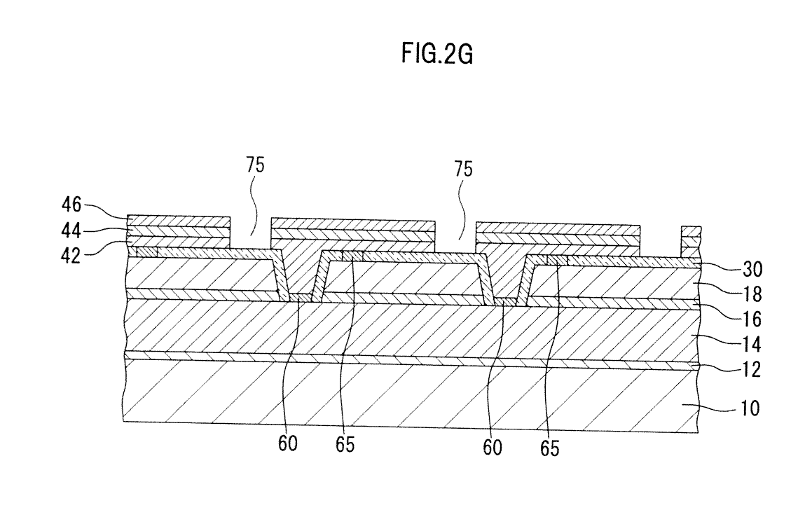

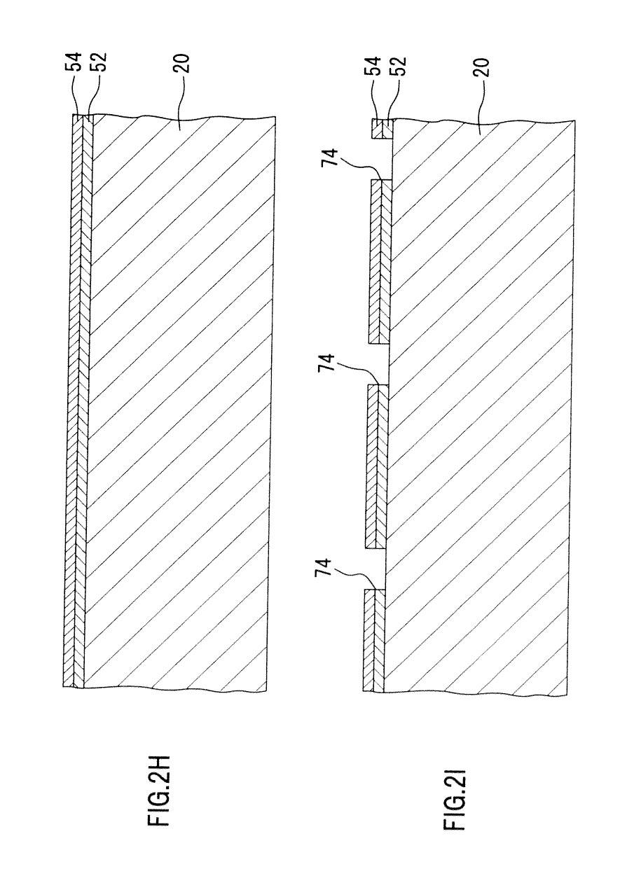

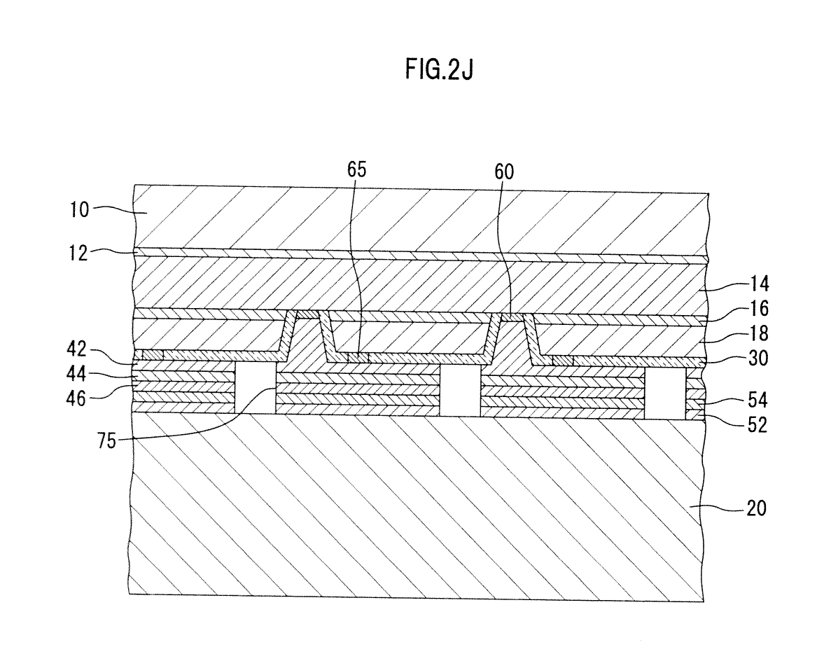

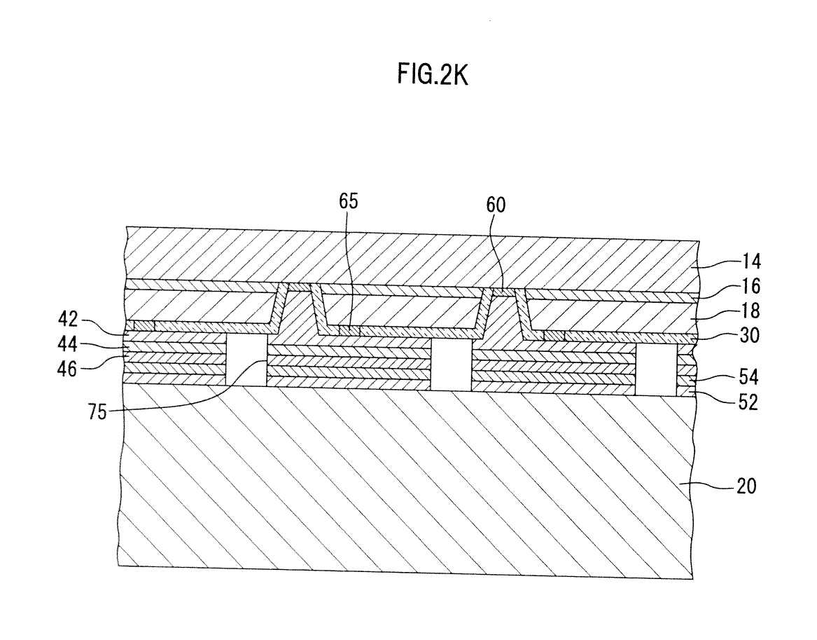

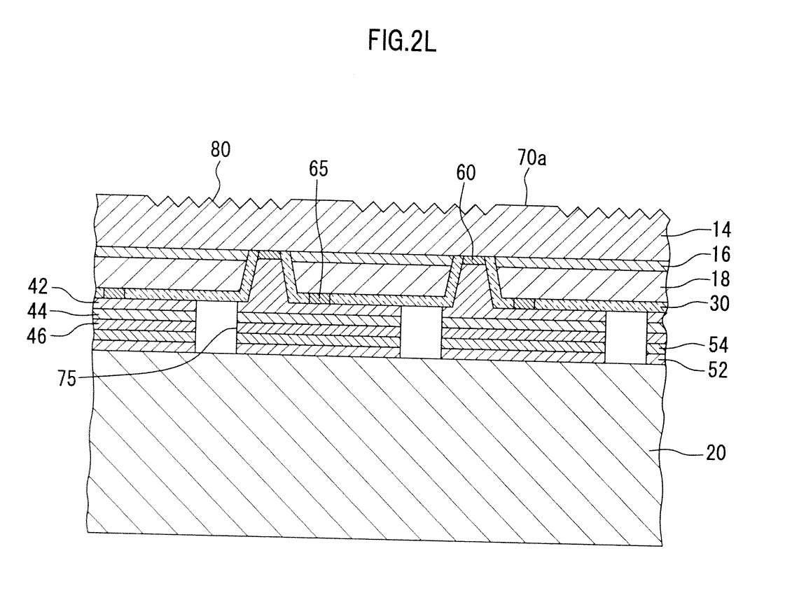

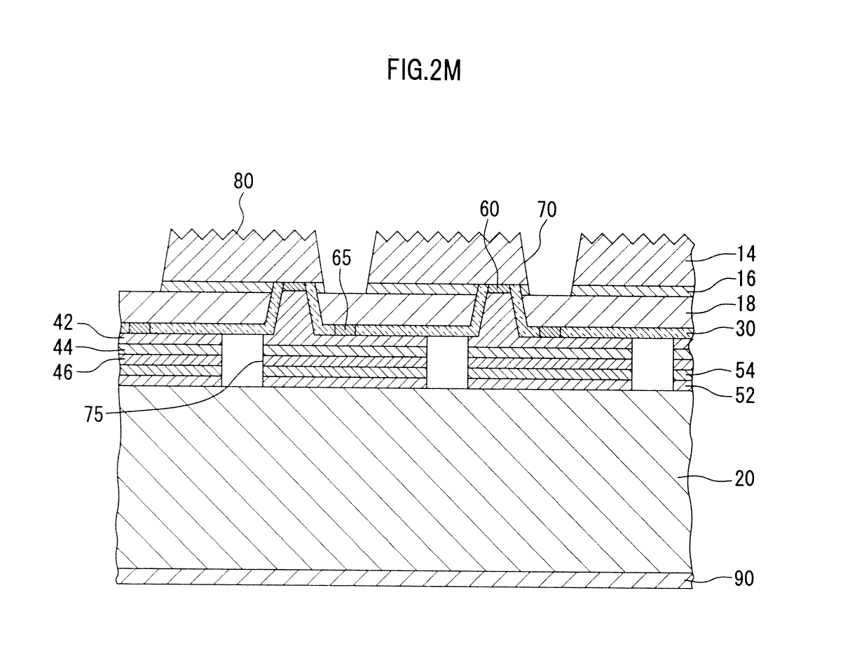

FIGS. 2A to 2M are cross-sectional views schematically showing an example of a flow of a manufacturing process of the light emitting device according to the embodiment of the present invention

The light emitting device 1 according to the embodiment is manufactured e g. by the following six steps. First, an epitaxial wafer is manufactured, and simultaneously the n-side contact electrode 60 and the p-side contact electrode 65 are formed on the epitaxial wafer (the first step). Next, the supporting substrate-side bonding layer 5 having a function as an electrode for small chip-wiring is formed on the supporting substrate 20 (the second step). Subsequently, the epitaxial wafer and the supporting substrate 20 are laminated with each other (the third step). In addition, the semiconductor layer 10 is removed from the epitaxial to wafer, and simultaneously the convexo-concave portions 80 are formed (the fourth step). Next, the groove 70 having a function as an isolation trench and a light absorption-preventing groove is formed, and simultaneously the metal layer 90 is formed on the back surface of the supporting substrate 20 (the fifth step). Finally, the chip-separation is carried out (the sixth step). Hereinafter, each step will be explained in detail.

### (The First Step)

First, the semiconductor layer 10 is prepared. As the semiconductor layer 10, e.g. a GaAs substrate may be used. Next, a semiconductor multilayer structure including a plurality of III-V group compound semiconductors is formed on the semiconductor layer 10 e g. by a metal organic chemical vapor deposition (MOCVD) method. Namely, the semiconductor multilayer structure including an etching stopper layer 12, the n-type cladding layer 14, the active layer 16, and the p-type cladding layer 18 in this order from a side of the semiconductor layer 10 is formed on the semiconductor layer 10. According to this step, the epitaxial wafer is manufactured (refer to FIG. 2A).

Here, the formation of the semiconductor multilayer structure by using the MOCVD method is carried out by setting a growth temperature, a growth pressure and a V/III ratio to a predetermined value respectively. Further, the V/III ratio means a ratio of molar ratio of V group materials such as arsine (AsH₃), phosphine (PH₃) to molar ratio of III group materials such as trimethylgallium (TMGa), trimethylaluminum (TMAl).

As sources used in the MOCVD method, an organometallic compound such as trimethylgallium (TMGa) or triethylgallium (TEGa) as a Ga raw material, trimethylaluminum (TMAl) as an Al raw material, and trimethylindium (TMIn) as an In raw material may be used. In addition, a hydride gas such as arsin (AsH₃) as an As source and phosphine (PH₃) as a P source may be used. Further, as a source of the n-type dopant, hydrogen selenide (H₂Se), disilane (Si₂H₆) may be used. Also, as a source of the p-type dopant, biscyclopentadienyl magnesium (Cp₂Mg) may be used.

In addition, as the source of the n-type dopant, monosilane (SiH₄), disilane (Si₂H₆), diethyl tellurium (DETe) or dimethyl tellurium (DMTe) may be also used. Also, as the source of the p-type dopant, dimethylzinc (DMZn) or diethylzinc (DEZn) may be also used instead of Cp₂Mg.

Next, after taking out the epitaxial wafer from the MOCVD equipment, a plurality of grooves 72 are formed by removing a part of the p-type cladding layer 18 and a part of the active layer 16 by using a photolithography method and an etching method (refer to FIG. 2B). Subsequently, the transparent insulation layer 30 is formed in a side of the plural grooves 72. Namely, the transparent insulation layer 30 is formed on the surface and the side surfaces of the p-type cladding layer 18, the side surfaces of the active layer 16 externally exposed by the plural grooves 72, and the surface of the n-type cladding layer 14. The transparent insulation layer 30 is formed e.g. by using a plasma chemical vapor deposition (CVD) equipment (refer to FIG. 2C)

Subsequently, a mask pattern is formed on the surface of the transparent insulation layer 30 in a region except for a region in which the n-side contact electrode 60 and the p-side contact electrode 65 are to be formed by using the photolithography method. In addition, after the mask pattern has been formed, an etching process is applied to the transparent insulation layer 30 with the use of the formed mask pattern as a mask. For example, in the case that the transparent insulation layer 30 is formed of SiO₂, the etching process may be carried out by using a hydrofluoric acid based etchant.

According to this step, an opening is formed by removing the transparent insulation layer 30 at a region on which the n-side contact electrode 60 and the p-side contact electrode 65 are to be formed. As a result, the surface 14a of the n-type cladding layer 14 corresponding to a region on which the n-side contact electrode 60 is to be formed is exposed, and simultaneously the surface 18a of the p-type cladding layer 18 corresponding to a region on which the p-side contact electrode 65 is to be formed is exposed from a through hole 30a (refer to FIG. 2D). Next, each of the n-side contact electrode 60 and the p-side contact electrode 65 is formed separately by using a vacuum deposition method. For example, after the n-side contact electrode 60 has been formed by using the photolithography method, the vacuum deposition method and a liftoff process, the p-side contact electrode 65 is formed by using the similar methods. Here, the n-side contact electrode 60 and the p-side contact electrode 65 are formed to have the approximately same thickness as a thickness of the transparent insulation layer 30 (refer to FIG. 2E). Further, the pad electrode for n-type 100 and the pad electrode for p-type 105 are formed at the same time.

Next, the semiconductor-side bonding layer 4 is formed on the surface of the supporting substrate 20, and the surfaces of the n-side contact electrode 60 and the p-side contact electrode 65. Namely, the semiconductor-side bonding layer 4 is formed on the surface of the transparent insulation layer 30, the surface being an opposite surface of a surface being in contact with the p-type cladding layer 18, and the surfaces of the n-side contact electrode 60 and the p-side contact electrode 65. The semiconductor-side bonding layer 4 may be formed by using the vacuum deposition method and a sputtering method and the like. For example, the semiconductor-side bonding layer 4 is formed by carrying out a film formation of an Au layer as the reflecting layer 42, a Ti layer as the diffusion suppressing layer 44 and an Au layer as the semiconductor-side bonding metal layer 46 in this order from the transparent insulation layer 3 (refer to FIG. 2F).

In addition, the plurality of grooves 75 are formed by removing a part of the semiconductor-side bonding layer 4 from a side of the surface of the semiconductor-side bonding layer 4 to a side of the transparent insulation layer 30 by using the photolithography method and the etching method (refer to FIG. 2G). Each of the grooves 75 has a function as a trench for separation of electrodes that prevents the p-side contact electrode 65 of the one light emitting portion and the n-side contact electrode 60 of the other light emitting portion adjacent to the one light emitting portion from being electrically connected to each other. According to this step, an epitaxial wafer with the semiconductor-side bonding layer 4 is manufactured.

Here, a cohesion layer that is capable of enhancing adhesion between the transparent insulation layer 30 and the reflecting layer 42 may be inserted between the transparent insulation layer 30 and the reflecting layer 42. The cohesion layer may comprise e.g. a metallic material. In addition, it is preferable that the cohesion layer is a layer in which absorption of the light emitted from the active layer 16 is reduced (i.e. a layer that has a high reflectance to the light). Subsequently, an alignment mark is formed on a back side of the semiconductor layer 10, i.e. at the predetermined location of a surface of the semiconductor layer 10, and the surface is an opposite surface of a surface on which the etching stopper layer 12 is provided (not shown). The alignment mark is used in the case that the epitaxial wafer with the semiconductor-side bonding layer 4 and the supporting substrate 20 with the supporting substrate-side bonding layer 5 described below are laminated with each other.

### (The Second Step)

First, the supporting substrate 20 is prepared. Then, the supporting substrate-side bonding layer 5 is formed on a surface of the supporting substrate 20. In particular, the cohesion layer 52 and the supporting substrate-side bonding metal layer 54 are formed in this order from a side of the surface of the supporting substrate 20 by using the vacuum deposition method and a sputtering method and the like (refer to FIG. 2H). The cohesion layer 52 may comprises e.g. a Ti layer, and the supporting substrate-side bonding metal layer 54 may comprise e.g. an Au layer. Next, a plurality of grooves 74 having a predetermined interval are formed in the supporting substrate-side bonding layer 5 by using the photolithography method and the etching method (refer to FIG. 2I). Then, an alignment mark is formed in the predetermined location of the back surface of the supporting substrate 20 (not shown). The alignment mark is used in the case that the epitaxial wafer with the semiconductor-side bonding layer 4 and the supporting substrate 20 are laminated with each other. According to this step, the supporting substrate 20 with the supporting substrate-side bonding layer 5 is formed.

### (The Third Step)

The surface of the epitaxial wafer with the semiconductor-side bonding layer 4 and the surface of the supporting substrate 20 with the supporting substrate-side bonding layer 5 are overlapped with each other to be facing to each other, and held in this state by a jig made from carbon or the like. Successively, the jig holding the contact state is introduced in a wafer bonding equipment having a function of alignment for a micro-machine. Then, the wafer bonding equipment is depressurized to a predetermined pressure. As an example, the predetermined pressure is set as 1.333 Pa (0.01 Torr). Then, a pressure is applied through the jig to the epitaxial wafer with the semiconductor-side bonding layer 4 and the supporting substrate 20 with the supporting substrate-side bonding layer 5 overlapped with each other. As an example, a pressure of 30 kgf/cm² is applied. Next, the jig is heated to a predetermined temperature with a predetermined rate of temperature elevation

For example, the temperature of the jig is raised to 350° C. After the temperature of the jig reached to about 350° C., the jig is held at the temperature for about 1 hour. Then, the jig is gradually cooled. The temperature of the jig is decreased enough e.g. to the room temperature. After the temperature of the jig is lowered, the pressure applied to the jig is released. After the pressure in the wafer bonding equipment is increased to an atmospheric pressure, the jig is taken out from the equipment. According to this process, the epitaxial wafer with the semiconductor-side bonding layer 4 and the supporting substrate 20 with the supporting substrate-side bonding layer 5 are mechanically bonded and electrically connected to each other between the semiconductor-side bonding layer 4 and the supporting substrate-side bonding layer 5 (refer to FIG. 2J). Further, hereinafter, a structure in a state that the epitaxial wafer with the semiconductor-side bonding layer 4 and the supporting substrate 20 with the supporting substrate-side bonding layer 5 are bonded is referred to as “a bonded structure”.

### (The Fourth Step)

Next, the bonded structure is laminated with an attaching wax on a jig of a lapping equipment. In particular, a surface on a side of the supporting substrate 20 is laminated to the jig. Consequently, a surface on a side of the semiconductor layer 10 is exposed externally. Then, the semiconductor layer 10 of the bonded structure is lapped to have a predetermined thickness (e.g. thickness of about 30 μm). Subsequently, the bonded structure after lapping is detached from the jig of the lapping equipment, and the wax bonded to the surface of the supporting substrate 20 is removed by cleaning. Then, after a film for etching protection made of photoresist is formed on the surface of the supporting substrate 20, the semiconductor layer 10 is selectively and sufficiently removed from the bonded structure by using an etchant for etching of the semiconductor layer 10, to form the bonded structure in which the etching stopper layer 12 is exposed. Since the etching stopper layer 12 is provided, the etching reaction is completed at the time when the semiconductor layer 10 is perfectly removed.

Further, in the case that the semiconductor layer 10 is formed of GaAs, as an etchant for etching of the semiconductor layer 10, a mixture of ammonia water and hydrogen peroxide water that is an etchant for etching of GaAs may be used. In addition, the whole semiconductor layer 10 may be also removed without lapping the semiconductor layer 10.

Subsequently, the etching stopper layer 12 is removed by using an etchant that selectively etches the etching stopper layer 12. For example, in the case that the etching stopper layer 12 comprises a GaInP based compound semiconductor, as the etchant that etches the etching stopper layer 12, hydrochloric acid may be used. According to this step, a surface of the n-type cladding layer 14 is exposed to the outside (refer to FIG. 2K).

Subsequently, the convexo-concave portions 80 formed in a conical shape having an apical portion of an acute angle are formed in the predetermined location of the surface of the n-type cladding layer 14 that is exposed by that the semiconductor layer 10 and the etching stopper layer 12 are removed by using the photolithography method and the vacuum deposition method. The convexo-concave portions 80 may be formed by using the photolithography method and the etching method. In particular, a mask is formed by using the photolithography method in a region in which the grooves 70 are to be formed. Then, the convexo-concave portions 80 are formed on the surface of the n-type cladding layer 14 in which the mask is not formed by using a dry etching method. According to this step, flat parts 70a that is a region in which the grooves 70 are to be formed and the convexo-concave portions 80 are formed on the surface of the n-type cladding layer 14 (refer to FIG. 2L).

### (The Fifth Step)

Next, a pattern for isolating elements from each other and a pattern for forming the grooves 70 are formed on the surface of the n-type cladding layer 14 by using the photolithography method. Then, a part from the surface of the n-type cladding layer 14 to the surface of the p-type cladding layer 18 is removed by the etching process with the use of the formed patterns as a mask. According to this step, the grooves 70 having a function of preventing dicing blades from coming into contact with a pn junction interface in the case of forming the light emitting device 1 by dicing are formed. Simultaneously, other grooves 70 having a function of defining a plurality of light emitting portions are formed. Also, by the etching process, a part of the reflecting portion 3, the pad electrode for n-type 100 and the pad electrode for p-type 105 are exposed to the outside. The exposed surfaces of the pad electrode for n-type 100 and the pad electrode for p-type 105 pass through a plurality of manufacturing steps, so that the adhesion between the wire may be lowered at the time of wire bonding. Accordingly, a film formation of an Au layer as an electrode for pad may be further carried out on the surfaces of the pad electrode for n-type 100 and the pad electrode for p-type 105. Next, the metal layer 90 is formed on the back surface of the supporting substrate 20. For example, an AuSn layer is formed on the back surface of the supporting substrate 20.

Subsequently, an alloying process is applied to the n-side contact electrode 60 and the p-side contact electrode 65 under an inert atmosphere. For example, a heating treatment is carried out on the n-side contact electrode 60 and the p-side contact electrode 65 under a nitrogen atmosphere for a predetermined time. According to this step, the n-side contact electrode 60 and the n-type cladding layer 14 are brought into ohmic contact with each other, and simultaneously the p-side contact electrode 65 and the p-type cladding layer 18 are brought into ohmic contact with each other (refer to FIG. 2M).

### (The Sixth Step)

Then, predetermined grooves 70 (i.e. the grooves 70 for isolating elements) are cut by using a dicing equipment. The other grooves 70 except the grooves 70 for isolating elements are not cut by dicing. According to this step, the light emitting device 1 according to the embodiment is manufactured. Further, the light emitting device 1 has a rectangular shape in a plan view, a device size (plane dimensions) of 1 mm square, and a thickness of about 200 μm, as an example.

### (Variations)

Conductivity type of compound semiconductors constituting the n-type cladding layer 14 and the p-type cladding layer 18 that the light emitting device 1 includes may be reversed to opposite conductivity type. Further, the active layer 16 may be formed to have any of quantum well structures, such as a single quantum well structure, a multiple quantum well structure, or a strained quantum well structure. Further, the compound semiconductors mainly constituting the light emitting device 1 according to the embodiment may be replaced with compound semiconductors such as GaAs, AlGaAs, and/or InGaAsP.

The n-side contact electrode 60 and the p-side contact electrode 65 may be formed to have such a shape in a plan view that dot-shaped electrodes are linearly arranged. Namely, it is also possible to provide shape that the n-side contact electrode 60 and the p-side contact electrode 65 are separated into a plurality of sections. In this case, each shape of the n-side contact electrode 60 and the p-side contact electrode 65 is not limited to a circle, but an ellipse, a rectangle, a circle with branch or the like may be also used.

### Advantages of the Embodiment

The light emitting device 1 according to the embodiment has a structure that the n-side contact electrode 60 and the p-side contact electrode 65 are not formed directly above or below the active layer 16. Therefore, an amount of incident light to the n-side contact electrode 60 and the p-side contact electrode 65 may be reduced in the case that a light emitted from the active layer 16 is extracted to the outside while the light repeats reflection in the light emitting device 1. Namely, it is possible to prevent a loss of the light caused by that the light emitted from the active layer 16 is absorbed by the n-side contact electrode 60 and the p-side contact electrode 65. Accordingly, in the light emitting device 1 according to the embodiment, it is possible to reduce the amount of the light absorbed by the n-side contact electrode 60 and the p-side contact electrode 65 (i.e. absorption loss of light by electrodes can be reduced), so that it is possible to prevent that the light emitted from the active layer 16 is converted to heat.

Further, in the light emitting device 1 according to the embodiment, it is not necessary to reduce an area of electrodes for the purpose of enhancing the light extraction efficiency different from the conventional light emitting device. Therefore, it is also possible to prevent the forward voltage of the light emitting device 1 from elevating. In addition, it is possible to reduce the repeat of reflection of light by electrodes in the light emitting device 1, so that a loss of light in the electrodes can be also reduced. Consequently, according to the light emitting device 1, it is possible to realize reduction of light absorption loss and lowering forward voltage in a low manufacturing cost.

In addition, the light emitting device 1 according to the embodiment has a structure that the n-side contact electrode 60 and the p-side contact electrode 65 are not formed directly above or below the active layer 16. Therefore, it is not necessary to develop electrodes having a high reflectance. Further, since the reduction in contact resistivity and enhancement of reflectance bear a relationship of trade-off, it is difficult to successfully combine the reduction in contact resistivity with the enhancement of reflectance. In the light emitting device 1 according to the embodiment, however, it is not necessary to consider the above-mentioned relationship of trade-off. Further, in the light emitting device 1 according to the embodiment, it is not necessary to develop electrodes having a low contact resistivity and to reduce the area of the electrode.

Conventionally, following technique has been used for enhancing the light emission efficiency. An area of chip is enlarged while an area of electrode is kept constant, thereby a ratio of the area of electrodes in a plan view to the area of the light emitting device in a plan view is lowered, and a ratio of a light entering the electrodes when the light is reflected in the chip is reduced, thereby a light absorption loss is reduced. However, in this case, the same electrical current is supplied to the light emitting device, so that the area of the light emitting device in a plan view is enlarged, and the number of the chips obtained from one wafer is reduced. As a result, the manufacturing cost is increased. However, the light emitting device 1 according to the embodiment has a structure that the n-side contact electrode 60 and the p-side contact electrode 65 are not formed directly above or below the active layer 16, so that the area of electrodes can be enlarged. In addition, even if the area of chip is not further enlarged, the light emission efficiency can be enhanced. Namely, according to the light emitting device 1, even if the area of electrodes is enlarged so as to reduce electrical current density, it is possible to reduce the forward voltage.

Further, the light emitting device 1 according to the embodiment has a structure that the n-side contact electrode 60 and the p-side contact electrode 65 are not formed directly above or below the active layer 16, so that the light emission efficiency is not lowered even if areas of the n-side contact electrode 60 and the p-side contact electrode 65 are enlarged. Furthermore, the epitaxial layer is formed thick, thereby an emission region can be enlarged even if the internal resistance is not lowered. Therefore, the emission of light in a location directly below the n-side contact electrode 60 and the p-side contact electrode 65 can be prevented, so that the degree of freedom of the electrode design can be increased.

In addition, the light emitting device 1 according to the embodiment has a structure that a plurality of the n-side contact electrodes 60 and a plurality of the p-side contact electrodes 65 are arranged in such a way that distances between the plurality of the n-side contact electrodes 60 and the plurality of the p-side contact electrodes 65 are maintained approximately constant, so that lengths of current passages between the electrodes (i.e. resistances between the electrodes) are also maintained approximately constant in any region. Accordingly, in the light emitting device I according to the embodiment, the electric current flowing through the n-side contact electrodes 60, the p-side contact electrodes 65 and the semiconductor layer is approximately uniform, so that the light can be emitted efficiently. Also, variation of the flowing electric current can be reduced, so that life time of the light emitting device 1 can be also prolonged.

Furthermore, in the light emitting device 1 according to the embodiment, a plurality of the light emitting portions 11 with the linear shape are arranged on a high resistance substrate or an insulation substrate, thereby even if the light emitting device 1 is grown in size, the number of the light emitting portion 11 can be increased while maintaining a state that the electrical currents flow approximately uniform, and the light emitting device 1 can be grown in size. Also, wiring of the electrodes is changed appropriately according to performance required for the light emitting device 1, thereby the light emitting device 1 of low voltage and high-current operation or the light emitting device 1 of high voltage and low-current operation can be also provided.

### The First Modification of the Embodiment

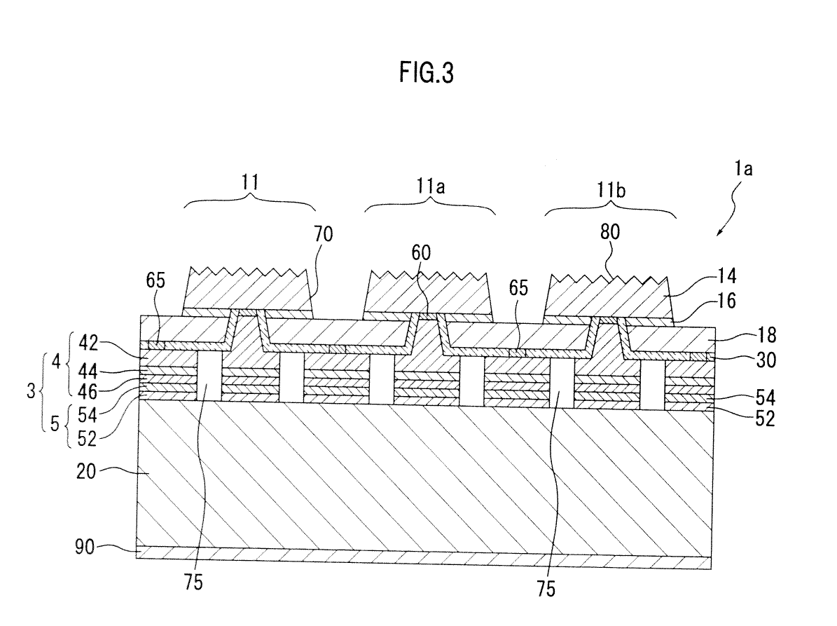

FIG. 3 is a cross-sectional view schematically showing a light emitting device according to a first modification of the embodiment of the present invention.

A light emitting device 1a according to the first modification has almost the same structure and function as the light emitting device 1 except for the point that in a sectional view, the p-side contact electrode 65 is arranged respectively in both sides of the respective light emitting portions 11 to 11b, and simultaneously in a plan view, the n-side contact electrode 60 is arranged respectively adjacent to the center of the respective light emitting portions 11 to 11b. Therefore, detail explanation will be omitted except for the different point.

In the light emitting device 1a, one light emitting portion (e.g. the light emitting portion 11) and an other light emitting portion adjacent to the one light emitting portion (e.g. the light emitting portion 11a) are electrically connected in parallel. For example, a case that the one light emitting portion is sandwiched between a first groove 70 and a second groove 70 is explained. Namely, first, a groove 75 is provided in the reflecting portion 3 located between the p-side contact electrode 65 located below the first groove 70 adjacent to the one light emitting portion and the n-side contact electrode 60 located below the one light emitting portion, and a groove 75 is provided in the reflecting portion 3 located between the p-side contact electrode 65 located below the second groove 70 opposite to the first groove 70 while sandwiching the one light emitting portion and the n-side contact electrode 60. According to this, a plurality of the p-side contact electrodes 65 are isolated with each other.

On the other hand, the p-side contact electrode 65 located below the first groove 70 and the n-side contact electrode 60 are electrically connected to each other via the p-type cladding layer 18, the active layer 16 and the n-type cladding layer 14. Similarly, the n-side contact electrode 60 and the p-side contact electrode 65 located below the second groove 70 are also electrically connected to each other via the p-type cladding layer 18, the active layer 16 and the n-type cladding layer 14. According to this, the one light emitting portion and the other light emitting portion are electrically connected in parallel. Further, each of the plural light emitting portions can be also connected to each other by that connection in series and connection in parallel are combined.

### The Second Modification of the Embodiment

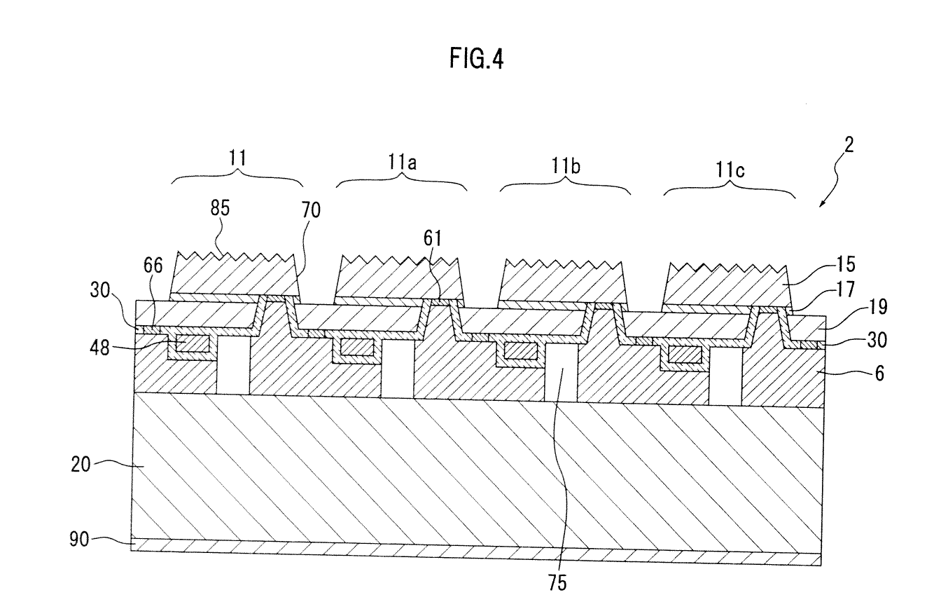

FIG. 4 is a cross-sectional view schematically showing a light emitting device according to a second modification of the embodiment of the present invention.

The light emitting device 2 according to the second modification mainly includes GaN based compound semiconductor, has a bonding layer 6 different in the configuration, and a reflecting portion 48 is provided between the transparent insulation layer 30 and the supporting substrate 20. In addition, each member to which the same references are attached as those of the light emitting device 1 has almost the same structure and function as each member included in the light emitting device 1. Accordingly, detail explanation is omitted except for the different point.

The light emitting device 2 according to the second modification is e.g. a light emitting diode that emits a blue light. The light emitting device 2 is manufactured, as an example, as follows. First, an n-type cladding layer 15 composed of n-type AlGaN, an active layer 17 composed of undoped InGaN, and a p-type cladding layer 19 composed of p-type AlGaN are epitaxially grown on a sapphire substrate so as to manufacture an epitaxial wafer. Subsequently, the p-type cladding layer 19 and the active layer 17 corresponding to a predetermined region of the epitaxial wafer, namely a region in which an n-side contact electrode 61 is to be formed, are removed by dry etching or the like, thereby grooves are formed.

Next, a film formation of the transparent insulation layer 30 is carried out on the surface of the epitaxial wafer having the grooves. The transparent insulation layer 30 is formed of e.g. a SiO₂ layer. Also, holes for forming electrodes are formed in each of regions of the transparent insulation layer 30 in which p-side contact electrodes 66 and the n-side contact electrodes 61 are to be formed. The surface of the p-type cladding layer 19 is exposed from the holes formed in regions in which the p-side contact electrodes 66 are to be formed and simultaneously the surface of the n-type cladding layer 14 is exposed from the holes formed in regions in which the n-side contact electrodes 61 are to be formed. In addition, each of the p-side contact electrode 66 and the n-side contact electrode 61 is separately formed in each of the holes.

Next, reflecting portions 48 are formed in parts of an opposite surface of a surface being in contact with the p-type cladding layer 19 of the transparent insulation layer 30. The reflecting portion 48 may be formed by using Ag having a high reflectance to a blue light. Here, Ag easily causes electromigration, thus after the reflecting portion 48 is formed, the reflecting portion 48 is sealed with SiO₂. The SiO₂ sealing the reflecting portion 48 is integrated with the transparent insulation layer 30. Subsequently, the bonding layer 6 is formed on an opposite surface of a surface being in contact with the p-type cladding layer 19 of the transparent insulation layer 30. The bonding layer 6 is formed of e.g. an Au layer. Further, a plurality of grooves are formed in the bonding layer 6 at a predetermined interval. According to this, the epitaxial wafer with the bonding layer 6 can be obtained.

Next, a Si substrate having a good thermal conductivity is used as the supporting substrate 20, and the supporting substrate 20 and the epitaxial wafer with the bonding layer 6 are laminated with each other in the same manner as the embodiment. Further, a metal layer including an Au layer may be preliminarily provided on the surface of the supporting substrate 20 which is laminated to the epitaxial wafer in the same manner as the embodiment. In addition, grooves 75 are formed in the Au layer so as to have the substantively same interval as that of the grooves 75 of the epitaxial wafer with the bonding layer 6. After laminated, the sapphire substrate is separated by using a laser lift-off method. Subsequently, the convexo-concave portions 80 are formed on the surface of the n-type AlGaN layer exposed due to the separation of the sapphire substrate by using the photolithography method and the dry etching method. According to this, the light emitting device 2 according to the second modification can be obtained.

### Third Modification of the Embodiment

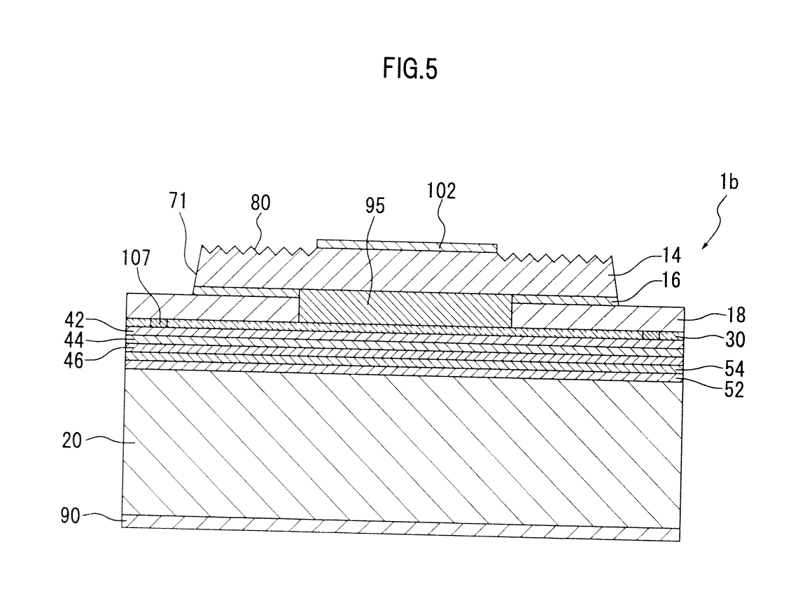

FIG. 5 is a cross-sectional view schematically showing a light emitting device according to a third modification of the embodiment of the present invention.

The light emitting device 1b according to the third modification has a structure that the active layer 16 and n-type cladding layer 14 located above an interface electrode 107 are removed by etching so as to form a light absorption preventing groove 71, and simultaneously an insulation portion 95 is formed in a region from which the active layer 16 and the p-type cladding layer 18 are removed, the region located directly below a surface electrode 102 having a function as a pad electrode for wire bonding, different from the light emitting device 1 according to the embodiment. In addition, each member to which the same references are attached as those of the light emitting device 1 has almost the same structure and function as each member included in the light emitting device 1. Accordingly, detail explanation is omitted except for the different point.

The light emitting device 1b is manufactured e.g. as follows. First, the n-type cladding layer 14, the active layer 16 and the p-type cladding layer 18 are epitaxially grown on a GaAs substrate in this order so as to form an epitaxial wafer. Next, the transparent insulation layer 30 is formed on the surface of the epitaxial wafer (i.e. the surface of the p-type cladding layer 18). Subsequently, holes are formed in the transparent insulation layer 30 corresponding to regions in which the interface electrodes 107 are to be formed. Then, the interface electrodes 107 are formed in the holes. The interface electrode 107 is formed by using a material that is brought into ohmic-contact with the p-type cladding layer 18.

Next, the semiconductor-side bonding layer 4 is formed on the surface of the transparent insulation layer 30 located in an opposite side of the p-type cladding layer 18. On the other hand, the supporting substrate 20 with the supporting substrate-side bonding layer 5 is prepared in the same manner the embodiment. Then, the semiconductor-side bonding layer 4 and the supporting substrate-side bonding layer 5 are metal-bonded to each other so as to form a bonded structure. After the GaAs substrate is removed from the bonded structure, a hole is formed in predetermined region of the active layer 16 and the p-type cladding layer 18. Then, the insulation portion 95 is formed in the hole. The insulation portion 95 is formed e.g. by using polyimide. Accordingly, polyimide is embedded in the hole and the surface of polyimide exposed to the outside is planarized, thereby the insulation portion 95 may be formed.

Next, a surface electrode 102 is formed on the surface of the n-type cladding layer 14 located above the insulation portion 95 The surface electrode 102 is formed by using a material that is brought into ohmic-contact with the n-type cladding layer 14. Subsequently, the convexo-concave portions 80 are formed on the surface of the n-type cladding layer 14 on which the surface electrode 102 is not formed, and simultaneously the active layers 16 and the n-type cladding layers 14 located above the interface electrodes 107 are removed by etching, thereby the light absorption preventing grooves 71 are formed. According to this, the light emitting device 1b according to the third modification can be obtained.

Further, from the viewpoints of practical utility in the manufacture of the light emitting device 1, enhancement of easiness in the manufacture and reduction in the manufacturing cost, the insulation portion 95 may be also formed as follows. Namely, after the epitaxial wafer is manufactured, the p-type cladding layer 18 and the active layer 16 located in a region on which the insulation portion 95 is to be formed are removed by etching so as to form a groove. Then, a material that is able to maintain an insulation property even if it passes through the third step e.g. polyimide is embedded in the groove. Subsequently, the surface of polyimide is planarized for the purpose of equalizing the surfaces of polyimide and the p-type cladding layer 18. Next, the transparent insulation layer 30 is formed on the surfaces of the p-type cladding layer 18 and polyimide. After that, almost the same steps as the above-mentioned steps are carried out, thereby the light emitting device 1b can be manufactured.

### The Fourth Modification of the Embodiment

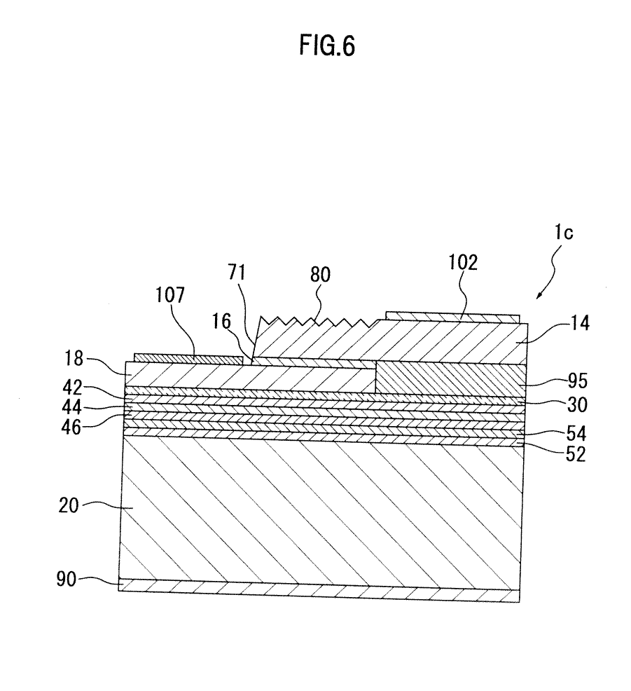

FIG. 6 is a cross-sectional view schematically showing a light emitting device according to a fourth modification of the embodiment of the present invention.

The light emitting device 1c has almost the same structure and function as the light emitting device 1b according to the second modification except for the point that the interface electrodes 107 is exposed to the outside and simultaneously the surface electrode 102 and the insulation portion 95 are provided in an end portion side of the light emitting device 1c. Accordingly, detail explanation is omitted except for the different point.

The interface electrodes 107 of the light emitting device 1c is formed on a part of the surface of the p-type cladding layer 18 exposed by that the active layer 16 and the n-type cladding layer 14 are removed, the part of the surface being located in a region adjacent to one side of the light emitting device 1c in a plan view. In addition, the insulation portion 95 is provided on a region directly below the surface electrode 102, from which the active layer 16 and the p-type cladding layer 18 are removed, the region being located in a side of an opposite side of the one side of the light emitting device 1c in a plan view

### EXAMPLE

As a light emitting device according to an Example, a light emitting device having a structure of the light emitting device 1 according to the embodiment was manufactured.

In the Example, first, a semiconductor multilayer structure was formed on an n-type GaAs substrate In particular, an etching stopper layer, an n-type AlGaInP cladding layer, a quantum well type AlGaInP active layer and a p-type AlGaInP cladding layer were epitaxially grown sequentially from a side of the n-type GaAs substrate by the MOCVD method.

Then, the light emitting device according to the Example was manufactured in line with the manufacturing method explained in the embodiment. Further, as a material constituting the transparent insulation layer 30, SiO₂ was used and as the supporting substrate 20, a Si substrate having a high resistance (resistivity: not less than 3×10⁴ Ωcm) was used. As the semiconductor-side bonding layer 4, an Au layer, a Ti layer and an Au layer are formed sequentially from a side of the Si substrate. In addition, eleven light emitting portions were formed and simultaneously each of the light emitting portions was connected in series.

Then, after a die bonding of the light emitting device according to the Example to a stem, a wire bonding was applied to the light emitting device. Then, a transparent resin mold was applied to the light emitting device so as to manufacture a light emitting apparatus. This light emitting apparatus was fixed to a radiator jig, and then a light emission property and an electrical property are evaluated. As a result, the driving current was 30 mA at forward current-carrying, the forward voltage was 24 V (since eleven light emitting portions were connected in series, the voltage became 24 V), the dominant wavelength was 625 nm and the light emission output was 480 mW. The external quantum efficiency of the light emitting device was approximately 76% and the light emission efficiency was 140 lm/W. The value of this light emission efficiency was a value improved by approximately 35% than the light emission efficiency of the conventional light emitting device. In addition, the light emitting device according to the Example was able to reduce the exothermic energy by 45% in comparison with the conventional light emitting device.

It is considered that the above-mentioned result that the light emission efficiency was able to be enhanced than the conventional one was caused by that the light emitting device according to the Example had a structure capable of drastically reducing the light absorption due to the n-side contact electrode 60 and the p-side contact electrode 65. Also, the fact that the high light emission output could be achieved by such a low applied current as 30 mA shows that the power supply system supplying electric power to the light emitting device is not needed to be compatible with high electrical current and a power supply compatible with low electrical current may be used.

In addition, considering that the light emitting diode is susceptible to heat generation and the heat generation affects the life time of the light emitting device, the reduction in exothermic energy shows that the limit value of the applied electrical current can be increased by 40%. Further, the reduction in exothermic energy shows that an amount of heat generation from the light emitting device becomes less than the conventional light emitting device in the case that the same electrical current is supplied. Therefore, it is also shown that the device lifetime of the light emitting device according to the Example becomes longer than that of the conventional light emitting device. Furthermore, if the light emitting device has the same device lifetime at the same electrical current, it can be also mounted on a stem that has a small size and a small radiation property. In particular, a power LED is needed to be improved in the radiation property. For example, in the case that the light emitting device according to the Example is applied to a bulb type LED, the radiation portion of the bulb type LED can be downsized than the conventional one, so that the bulb type LED can be provided at a lower cost than the conventional one.

As described above, the light emitting device according to the Example not only can enhance the light emission efficiency but also can realize an increase in service life of the device lifetime, a downsizing and a reduction of the manufacturing cost of the light emitting device.

Although the invention has been described, the invention according to claims is not to be limited by the above-mentioned embodiments and examples. Further, please note that not all combinations of the features described in the embodiments and the examples are not necessary to solve the problem of the invention.

What is claimed is:

1. A light emitting device, comprising:
a supporting substrate;
a first conductivity type layer of a first conductivity type provided on the supporting substrate;
an active layer provided on the first conductivity type layer, which emits a light;
a second conductivity type layer of a second conductivity type provided on the active layer, the second conductivity type being different from the first conductivity type;
a first electrode being in contact with a part of a surface of the first conductivity type layer; and
a second electrode being in contact with a part of a surface of the second conductivity type layer,
wherein the first electrode is in contact with a surface of the first conductivity type layer, the surface being different from a surface of the first conductivity type layer corresponding to a region located directly above or below the active layer,
wherein the second electrode is in contact with a surface of the second conductivity type layer, the surface being different from a surface of the second conductivity type layer corresponding to a region located directly above or below the active layer.

2. The light emitting device according to claim 1, wherein the first electrode comprises a plurality of electrodes and the second electrode comprises a plurality of electrodes, the first electrode and the second electrode are formed in a linear shape respectively in a plan view, and the first electrode and the second electrode are arranged parallel to each other in a plan view.

3. The light emitting device according to claim 2, further comprising:
a plurality of light emitting portions provided on the supporting substrate, each of the light emitting portions comprising the first conductivity type layer and the active layer and being separated from each other by a plurality of grooves,
wherein the second electrode is provided on a surface of the second conductivity type layer located below each of the plurality of grooves and the surface is located on an opposite side of the active layer,
wherein the first electrode is provided on a surface of the first conductivity type layer in each of the plurality of light emitting portions, and the surface is located on a side of the second conductivity type layer and on which the active layer is not provided.

4. The light emitting device according to claim 3, further comprising:
a reflecting portion provided between the supporting substrate and the second conductivity type layer, which reflects the light toward the first conductivity type layer, and
a transparent insulation layer provided on a region between the reflecting portion and the second conductivity type layer, the region being different from a region on which the second electrode is provided, which transmits the light and has an electrical insulating property.

5. The light emitting device according to claim 4, wherein the first electrode in one light emitting portion and the second electrode in an other light emitting portion adjacent to the one light emitting portion are electrically connected to each other, thereby the one light emitting portion and the other light emitting portion are electrically connected in series.

6. The light emitting device according to claim 4, wherein the first electrode in one light emitting portion and the first electrode in an other light emitting portion adjacent to the one light emitting portion are electrically connected to each other, and the second electrode in the one light emitting portion and the second electrode in the other light emitting portion adjacent to the one light emitting portion are electrically connected to each other, thereby the one light emitting portion and the other light emitting portion are electrically connected in parallel.

7. A light emitting device, comprising:
a supporting substrate;
a first conductivity type layer of a first conductivity type provided on the supporting substrate;
an active layer provided on the first conductivity type layer, which emits a light;
a second conductivity type layer of a second conductivity type provided on the active layer; the second conductivity type being different from the first conductivity type;
a first electrode being in contact with a surface of the first conductivity type layer, the surface being located on an opposite side of the active layer and located distant from a region located directly below the active layer;
a second electrode being in contact with a part of a surface of the second conductivity type layer, the surface being located on an opposite side of the active layer; and
an insulation portion provided on a region corresponding to a region located directly below the second electrode instead of the active layer.

8. A light emitting device, comprising:
a supporting substrate;
a first conductivity type layer of a first conductivity type provided on the supporting substrate;
an active layer provided on the first conductivity type layer, which emits a light;
a second conductivity type layer of a second conductivity type provided on the active layer, the second conductivity type being different from the first conductivity type;
a first electrode being in contact with a surface of the first conductivity type layer, the surface being located on a side of the active layer and exposed from a region in which the active layer is removed;
a second electrode being in contact with a part of a surface of the second conductivity type layer, the surface being located on an opposite side of the active layer; and
an insulation portion provided on a region corresponding to a region located directly below the second electrode instead of the active layer.
